(19) United States
(12) Patent Application Publication
(10) Pub. No.: US 2014/0154415 A1
(43) Pub. Date: Jun. 5, 2014

(54) METHOD FOR MANUFACTURING SILICON-CONTAINING FILM

(71) Applicants: Atsushi Tomyo, Osaka-shi (JP); Yoshiyuki Nasuno, Osaka-shi (JP)

(72) Inventors: Atsushi Tomyo, Osaka-shi (JP); Yoshiyuki Nasuno, Osaka-shi (JP)

(73) Assignee: SHARP KABUSHIKI KAISHA, Osaka-shi, Osaka (JP)

(21) Appl. No.: 14/234,465

(22) PCT Filed: May 31, 2012
(86) PCT No.: PCT/JP2012/064107

§ 371 Date: Jan. 23, 2014

(30) Foreign Application Priority Data
Jul. 27, 2011 (JP) 2011-164253

(51) Int. Cl. C23C 26/00; C23C 16/24

(52) U.S. Cl. CPC C23C 26/00; C23C 16/24
USPC 427/248.1

(57) ABSTRACT

A method for manufacturing a silicon-containing film includes the steps of loading a substrate, depositing a silicon-containing unloading the substrate, dry cleaning, reducing fluoride and exhausting gas. In the step of reducing fluoride, a reducing gas is supplied into a chamber in such a way that a partial pressure of CF₄ gas in the chamber is A×(2.0×10⁻⁴) Pa or less at the end of the step of exhausting gas.

### TECHNICAL FIELD

The present invention relates to a method for manufacturing a silicon-containing film.

### BACKGROUND ART

Generally, a chemical vapor deposition (hereinafter, abbreviated as CVD where appropriate) method is employed to deposit a silicon film to be used in a thin-film solar cell or the like. In the growth of a silicon film according to the CVD method, impurities may adhere to an inner wall surface of a chamber in a CVD device or to a surface of a jig disposed in the chamber, and the adhered impurities may become foreign substances to be blended into the film growing in the chamber, which consequently leads to an increasing occurrence of crystal defects or the like in the film growing in the chamber.

In order to prevent the occurrence of such defects, for example, PTD 1 (Japanese Patent Laying-Open No. 2002-60951) has disclosed such a technique that after the chamber is dry-cleaned by using a fluorine-containing gas such as NF₃, the fluorine-based residual in the chamber is removed through hydrogen plasma, and thereafter, the fluorine-based residual in the chamber which has not been removed by hydrogen plasma is encapsulated in the plasma of a material gas for the silicon film.

### CITATION LIST

### Patent Document

PTD 1: Japanese Patent Laying-Open No. 2002-60951

### SUMMARY OF INVENTION

### Technical Problem

The composition of the fluorine-based residual remained in the chamber after dry cleaning varies with a state of the chamber (such as the material type of a member disposed in the chamber, the temperature of a heater, and the temperature of an inner wall of the chamber) or a film deposition history. Further, the fluorine-based residual will combine with other elements to produce fluorides in various forms, and thereby, which compound should be targeted at is unclear. Therefore, in order to remove the fluorine-based residual, it is necessary to establish some sort of monitoring methods for identifying which compound to be targeted at.

The present invention has been accomplished in view of the aforementioned problems, and it is therefore an object of the present invention to provide a method for manufacturing a silicon-containing film capable of reducing an amount of fluorides in a chamber during a period after a dry cleaning has been performed to a time when a subsequent film deposition (deposition of a silicon-containing film) is performed.

### Solution to Problem

The method for manufacturing a silicon-containing film according to the present invention includes a first step of loading a substrate into a chamber, a second step of depositing a silicon-containing film on a surface of the substrate in the chamber, a third step of unloading the substrate deposited with the silicon-containing film out of the chamber, a fourth step of dry cleaning the chamber with a fluoride-containing gas, a fifth step of supplying a reducing gas into the chamber to reduce fluoride present in the chamber, and a sixth step of exhausting gas in the chamber until an ultimate vacuum of the chamber is A (Pa). In the fifth step, the reducing gas is supplied into the chamber in such a way that a partial pressure of CF₄ gas in the chamber is A×(2.0×10⁻⁴) Pa or less at the end of the sixth step.

It is preferable that the first step, the second step, the third step, the fourth step, the fifth step and the sixth step are performed repeatedly.

It is preferable that the fifth step and the sixth step are additionally performed between the first step and the second step.

It is preferable that the reducing gas contains SiH₄ gas.

It is acceptable that the fifth step is performed under at least one condition among a condition that a supply time of the reducing gas is 10 to 1800 seconds, a condition that a flow rate of the reducing gas is 1000 to 100000 sccm (standard cc/min), and a condition that an internal pressure of the chamber is 300 to 5000 Pa.

It is preferable that a seventh step of performing a hydrogen plasma treatment in the chamber is further included subsequent to the sixth step.

It is acceptable that the seventh step is performed under at least one condition among a condition that a treatment time of the hydrogen plasma treatment is 1 to 10000 seconds, a condition that a flow rate of hydrogen gas is 10000 to 100000 sccm, a condition that an internal pressure of the chamber is 300 to 800 Pa, a condition that a pulsed discharge is performed at an applied electrical power of 0.03 to 0.1 W/cm² and a duty ratio of 5% to 50%, and a condition that a temperature of a heater for heating the substrate is 20 to 200° C. Here, the duty ratio is calculated by dividing a pulse width of an active RF pulse by a period thereof.

It is preferable that the silicon-containing film is deposited on the surface of the substrate according to a chemical vapor deposition method in the second step.

It is preferable that the reducing gas is supplied into the chamber in the fifth step in such a way that a partial pressure of CF₄ gas in the chamber is A×(2.5×10⁻⁵) Pa or more at the end of the sixth step.

A method of manufacturing a photovoltaic device according to the present invention includes the method of manufacturing a silicon-containing film according to the present invention.

### ADVANTAGEOUS EFFECTS OF INVENTION

According to the method of manufacturing a silicon-containing film according to the present invention, it is possible to reduce the amount of fluorides in the chamber during a period after a dry cleaning has been performed to a time when a subsequent film deposition is performed.

### BRIEF DESCRIPTION OF DRAWINGS

FIG. 1 is flow chart exemplifying a method for manufacturing a silicon-containing film according to the present invention;

FIG. 2 is a cross sectional view schematically illustrating a CVD device used in Examples 1 to 3;

FIG. 3 is a graph showing a measurement result of a partial pressure of a fluoride relative to a supply time of SiH₄ gas;

FIG. 4 is a graph showing measurement results of the partial pressure of CF₄ gas and the maximum output Pmax of a solar cell, respectively, relative to the supply time of SiH₄ gas;

FIG. 5 is a graph showing a relationship between the partial pressure of CF₄ gas and the maximum output Pmax of a solar cell, and

FIG. 6 is a graph showing a measurement result of the partial pressure of CF₄ gas relative to the supply time of SiH₄ gas.

### DESCRIPTION OF EMBODIMENTS

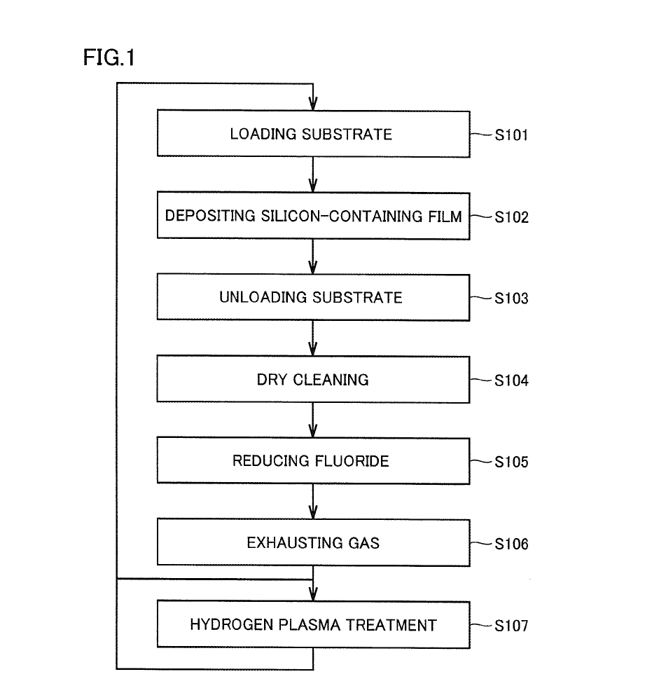

Hereinafter, a method for manufacturing a silicon-containing film according to the present invention and a method for manufacturing a photovoltaic device according to the present invention will be described. FIG. 1 is a flow chart exemplifying a method for manufacturing a silicon-containing film according to the present invention.

It should be noted that the present invention is not limited to any of the examples to be described below.

<Method for Manufacturing Silicon-Containing Film>

The method for manufacturing a silicon-containing film according to the present invention includes a step of loading a substrate into a chamber (“loading substrate ” in FIG. 1) S101, a step of depositing a silicon-containing film on a surface of the substrate in the chamber (“depositing silicon-containing film” in FIG. 1) S102, a step of unloading the substrate deposited with the silicon-containing film out of the chamber (“unloading substrate” in FIG. 1) S103, a step of dry cleaning the chamber (“dry cleaning” in FIG. 1) S104; a step of reducing fluoride present in the chamber (“reducing fluoride” in FIG. 1) S105, and a step of exhausting gas out of the chamber (“exhausting gas” in FIG. 1) S106. It is preferable that these steps are performed repeatedly in the same chamber, and it is also preferable that these steps are performed repeatedly in the order of the step of loading a substrate S101, the step of depositing a silicon-containing film S102, the step of unloading the substrate S103, the step of dry cleaning S104, the step of reducing fluoride S105 and the step of exhausting gas S106. As mentioned, in the method for manufacturing a silicon-containing film according to the present invention, the fluoride present in the chamber is reduced after the dry cleaning, and thereafter, the process proceeds to a subsequent film deposition step (deposition step of the silicon-containing film). Thus, according to the method for manufacturing a silicon-containing film according to the present invention, it is possible to reduce the amount of fluorides in the chamber during a period after the dry cleaning has been performed to a time when a subsequent film deposition is performed.

Moreover, it is preferable that the method for manufacturing a silicon-containing film according to the present invention further includes a step of performing a hydrogen plasma treatment to the substrate (“hydrogen plasma treatment” in FIG. 1) S107 subsequent to the step of reducing fluoride S105. Thereby, it is possible to reduce the amount of Si particles generated in the reduction reaction of fluorides during the period after the dry cleaning has been performed to a time when a subsequent film deposition is performed.

<Loading Substrate>

In the step of loading a substrate S101, the substrate is loaded into the chamber and fixed at a predetermined position in the chamber.

The material, the shape and the like of the substrate are not limited in particular. It is preferable that the substrate is made of for example, glass or the like. A surface of the substrate for depositing thereon a film may be even or uneven. The planar shape of the substrate may be a polygonal shape such as a rectangle or may be a circular shape.

<Depositing Silicon-Containing Film>

In the step of depositing a silicon-containing film S102, the silicon-containing film is deposited on the surface of the substrate placed in the chamber.

The method for depositing a silicon-containing film on the surface of the substrate is not limited in particular, it may be a CVD method or a plasma CVD method. In the case of depositing a silicon-containing film according to the CVD method, it is necessary to supply a source gas serving as a raw material of the silicon-containing film and a carrier gas into the chamber. In the case of depositing a silicon-containing film according to the plasma CVD method, it is necessary to ionize the source gas into plasma in the chamber while the source gas and the carrier gas are being supplied.

The material of the silicon-containing film is not limited in particular. The silicon-containing film may be, for example, a film consisting of silicon only, a silicon film containing p-type impurities (p-type silicon film), a silicon film containing n-type impurities (n-type silicon film), a silicon carbide film or a silicon nitride film, or may be a layered structure of these films. As the source gas of the silicon-containing film, for example, SiH₄ gas, Si₂H₆ gas or the like may be used. As the carrier gas, for example, nitrogen gas, hydrogen gas or the like may be used alone, or a mixed gas thereof may be used.

The thickness of the silicon-containing film is not limited in particular, and it may be 0.001 to 10 μm, and preferably be 0.005 to 5 μm. Thus, it is possible to use the obtained silicon-containing film as a component of a photovoltaic device.

The source gas and the carrier gas contact not only the surfaces of the substrate but also the inner wall surface of the chamber and/or surfaces of a member disposed in the chamber (hereinafter, “the inner wall surface of the chamber” and “surfaces of a member disposed in the chamber” are collectively referred to as “the inner wall surface and the like of the chamber”). Thereby, the impurities containing at least one of the source gas and the carrier gas may adhere to the inner wall surface and the like of the chamber.

If the deposition of the silicon-containing film is performed once more while the impurities are adhering to the inner wall surface and the like of the chamber, some of the elements constituting the impurities are incorporated into the silicon-containing film during growth, which may increase the number of crystal defects in the silicon-containing film during growth and thereby deteriorate characteristics of the silicon-containing film. Thus, in the manufacturing method of a silicon-containing film according to the present invention, as to be described in the following, after the step of <Substrate Unloading >, the step of <Dry Cleaning> is performed.

<Unloading Substrate>

In the step of unloading the substrate S103, the substrate deposited with the silicon-containing film is unloaded out of the chamber. The substrate unloaded out of the chamber can be used to manufacture a photovoltaic device or the like, for example.

<Dry Cleaning>

In the step of dry cleaning S104, the chamber is dry cleaned by using a fluorine-containing gas. The fluorine-containing gas is not limited to F₂ gas only, it also contains a composite gas formed through combination of fluorine and other elements not involving fluorine. Specifically, the fluorine-containing gas may be NF₃ gas, F₂ gas, C₂F₆ gas or the like. The dry cleaning is not limited to any method in particular, it may be performed by using discharging electrodes (for example, tabular discharging electrodes disposed parallel to each other) or according to a remote plasma method. According to the dry cleaning, the silicon-containing film adhered to places other than the substrate will be removed.

However, in the dry cleaning step, the silicon-containing film deposited on the inner wall surface and the like of the chamber in the above step of <Depositing Silicon-Containing Film> will be fluorinated. As examples of produced fluorides, for example, SiF₄ gas produced by reacting Si deposited on the inner wall surface and the like of the chamber in the above step of <Depositing Silicon-Containing Film> with fluorine, HF gas produced by reacting hydrogen gas which serves as the carrier gas in the above step of <Depositing Silicon-Containing Film> with fluorine, CF₄ gas produced by reacting SiC deposited on the inner wall surface and the like of the chamber in the above step of <Depositing Silicon-Containing Film> with fluorine, and the like may be given.

In general, the inner wall surface and the like of the chamber are made of metal such as SUS (Steel Use Stainless) or Al. Thus, the produced fluorides are immobilized (through chemical adsorption) on the inner wall surface and the like of the chamber and will not be eliminated from the chamber through vacuum evacuation or the like. If the above step of <Depositing Silicon-Containing Film> is performed once more under this circumstance, the fluorides (such as SiF₄ gas, HF gas and CF₄ gas) immobilized on the inner wall surface and the like of the chamber are reduced by SiH₄ gas, Si₂H₆ gas or the like contained in the source gas and released to the interior space of the chamber, and the released fluorides may be incorporated into the silicon-containing film during growth. In particular, if carbon atoms originated from CF₄ gas are incorporated excessively into a p-type silicon film during growth, it leads to a decrease in an open-circuit voltage Voc and an increase in a series resistance Rs of a photovoltaic device, which thereby degrades the maximum output Pmax. Thus, in the manufacturing method of a silicon-containing film according to the present invention, the following step of <Reducing Fluoride> is performed after the dry cleaning.

<Reducing Fluoride>

In the step of reducing fluoride S105, a reducing gas is supplied into the chamber. Thereby, the fluorides present in the chamber are reduced. Here, “the fluorides present in the chamber” means the fluorides (fluoride gases such as SiF₄ gas, HF gas and CF₄ gas) immobilized on the inner wall surface and the like of the chamber. Moreover, that “the fluorides present in the chamber are reduced” means that the immobile state between the fluorides and the inner wall surface and the like of the chamber is released. Then, the reduced fluorides (i.e., the fluoride gases whose immobile state with the inner wall surface and the like of the chamber has been released are exhausted out of the chamber through vacuum evacuation. Accordingly, it is possible to prevent the fluorides from being incorporated into the silicon-containing film during growth when performing once more the above step of <Depositing Silicon-Containing Film>.

The reducing gas may be any gas capable of reducing the fluorides present in the chamber, such as SiH₄ gas or Si₂H₆ gas. A single gas of these gases or a mixed gas thereof may be used as the reducing gas.

The reducing gas may be or may not be treated with plasma. If the reducing gas is not treated with plasma, it is possible for it to reduce the fluorides immobilized at a position distant from a plasma discharging region on the inner wall surface and the like of the chamber. Moreover, if the reducing gas is not treated with plasma, it is possible to obtain greater effects in the case where the inner wall surface and the like of the chamber are made of SUS-based materials. It should be noted that the method for manufacturing a silicon-containing film according to the present invention is not limited to the case where the inner wall surface and the like of the chamber are made of SUS-based materials, it is also possible for it to obtain the same effects (capable of reducing the fluorides present in the chamber) in the case where the inner wall surface and the like of the chamber are made of Al-based materials.

As described in the above step of <Dry Cleaning>, the method for manufacturing a silicon-containing film according to the present invention is aimed at exhausting CF₄ gas present in the chamber to the outside of the chamber before performing once more the above step of <Depositing Silicon-Containing Film>. It is preferable that the reducing gas to be supplied into the chamber satisfies at least one of the following conditions 1 to 3:

condition 1: the supply time of the reducing gas is 10 to 1800 seconds,

condition 2: the flow rate of the reducing gas is 1000 to 100000 sccm, and

condition 3: the internal pressure of the chamber is 300 to 5000 Pa.

If the supply time of the reducing gas is less than 10 seconds, it is difficult to sufficiently reduce the fluorides present in the chamber, and thereby, the partial pressure of CF₄ gas in the chamber may exceed A×(2.0×10⁻⁴) Pa at the end of the step of <Exhausting Gas> to be described hereinafter. The same applies to the case where the flow rate of the reducing gas is below 1000 sccm. On the other hand, if the supply time of the reducing gas is more than 1800 seconds, it is difficult to further lower the partial pressure of CF₄ gas in the chamber. The same applies to the case where the flow rate of the reducing gas exceeds 100000 sccm.

If the internal pressure of the chamber is less than 300 Pa, the reduction reaction of the fluoride does not proceed efficiently, leading to such a problem that the take time is prolonged, which thereby deteriorates the productivity of the silicon-containing film. On the other hand, if the internal pressure of the chamber is more than 5000 Pa, such a problem may occur that a large load is applied to a pressure regulating valve, a vacuum pump, and an exhausted gas treating equipment or the like attached to the chamber.

However, if the reducing gas is supplied satisfying at least one of the conditions 1 to 3, the partial pressure of CF₄ gas in the chamber at the end of the following step of <Exhausting Gas> will be A×(2.0×10⁻⁴) Pa or less. Thus, it is possible to reduce the amount of CF₄ gas remaining in the chamber at the end of the following step of <Exhausting Gas>. Accordingly, even though the above step of <Depositing Silicon-Containing Film> is performed once more, it is possible to prevent CF₄ gas (especially carbon atoms) from being incorporated into the silicon-containing film during growth to deteriorate the performance of the silicon-containing film. Therefore, if a photovoltaic device is manufactured by using the method for manufacturing a silicon-containing film according to the present embodiment, it is possible to offer the photovoltaic device without deteriorating the performance thereof (for example, degrading the maximum output). Note that the above value “2.0×10⁻⁴” is based on the results of Examples 1 to 3 to be described below.

Further, if the reducing gas is supplied satisfying at least one of the conditions 1 to 3, the partial pressure of CF₄ gas in the chamber at the end of the following step of <Exhausting Gas> may be A×(5.0×10⁻⁵) Pa or less. Accordingly, the above mentioned effect will become more significant, in other words, even though the above step of <Depositing Silicon-Containing Film> is performed once more, it is possible to prevent CF₄ gas (especially carbon atoms) from being incorporated into the silicon-containing film during growth to deteriorate the performance of the silicon-containing film.

Furthermore, if the reducing gas is supplied satisfying at least one of the conditions 1 to 3, the partial pressure of CF₄ gas in the chamber at the end of the following step of <Exhausting Gas> can be A×(2.5×10⁻⁵) Pa or more. Accordingly, it is possible to prevent the partial pressure of CF₄ gas in the chamber from becoming excessive low at the end of the following step of <Exhausting Gas> to degrade the maximum output Pmax.

Herein, the abovementioned “A” is an ultimate vacuum of the chamber, which is the total pressure (the sum of partial pressures of all gases present in the chamber) in the chamber at the end of the following step of <Exhausting Gas>. The value “A” may be set appropriately, and it is preferable to set it to 10 Pa or less. If value “A” is 10 Pa or less, it is possible to make lower the partial pressure of CF₄ gas in the chamber at the end of the following step of <Exhausting Gas>.

Although not limited in particular, as a measurement method for the partial pressure of CF₄ gas in the chamber, the quadrupole mass spectrometry is suitable.

The fluorides may be reduced after the above step of <Dry Cleaning> and before the above step of <Depositing Silicon-Containing Film> is performed once more. Specifically, the fluorides may be reduced after the above step of <Dry Cleaning>, and thereafter, the above step of <Loading Substrate> is performed once more. Alternately, the above step of <Loading Substrate> is performed once more after the above step of <Dry Cleaning>, and thereafter, the fluorides are reduced. In other words, the fluorides may be reduced before the substrate to be deposited with the silicon-containing film is placed in the chamber or after the substrate to be deposited with the silicon-containing film has been placed in the chamber. The same applies to the following step of <Exhausting Gas>. However, for reasons described below, it is preferable that the fluorides are reduced before the substrate to be deposited with the silicon-containing film is placed in the chamber.

If the fluorides are reduced after the substrate to be deposited with the silicon-containing film has been placed in the chamber, a portion of the inner wall surface and the like of the chamber where the substrate has been positioned (for example, the upper surface of the anode electrode) is not exposed to the reducing gas. If the above sequence of steps is repeated under such circumstance, the fluorides will deposit on the upper surface of the anode electrode, and the fluorides deposited on the upper surface of the anode electrode will adhere to the back surface of the substrate. If the back surface or the like of the substrate adhered with the fluorides is subjected to a laser treatment, problems may occur in the treatment.

Further, even if the fluorides are reduced after the substrate deposited with the silicon-containing film has been placed in the chamber, a small amount of SiH₄ gas may flow to the upper surface of the anode electrode and be immobilized on the upper surface of the anode electrode. Thus, when the above step of <Depositing Silicon-Containing Film> is performed once more, the fluorides immobilized on the upper surface of the anode electrode may be reduced, and the reduced fluorides may be incorporated into the silicon-containing film during growth. Accordingly, it is possible to degrade the performance of the silicon-containing film, and consequently degrade the performance of a semiconductor device (such as a photovoltaic device) manufactured by using the obtained silicon-containing film.

It is preferable that the fluorides are additionally reduced between the above step of <Loading Substrate> and the above step of <Depositing Silicon-Containing Film>. Thereby, it is possible to further lower the partial pressure of CF₄ gas in the chamber before the above step of <Depositing Silicon-Containing Film> is performed once more. The same applies to the following step of <Exhausting Gas>.

After the reducing gas has been supplied into the chamber in such a way that the partial pressure of CF₄ gas in the chamber is A×(2.0×10⁻⁴) Pa or less at the end of the following step of <Exhausting Gas>, preferably the partial pressure of CF₄ gas in the chamber is A×(5.0×10⁻⁵) Pa or less at the end of the following step of <Exhausting Gas>, and more preferably the partial pressure of CF₄ gas in the chamber is A×(2.5×10⁻⁵) Pa or more at the end of the following step of <Exhausting Gas>, the step of <Reducing Fluoride> is ended. Thereafter, the following step of <Exhausting Gas> is performed.

<Exhausting Gas>

In the step of exhausting gas S106, the gas in the chamber is exhausted until the ultimate vacuum of the chamber reaches A (Pa). Although not limited in particular, it is preferable to exhaust the gas from the chamber through vacuum evacuation. Thereafter, the above step of <Loading Substrate> may be performed once more, the above step of <Loading Substrate> may be performed once more after the following step of <Hydrogen Plasma Treatment>.

<Hydrogen Plasma Treatment>

In the step of performing a hydrogen plasma treatment S107, the hydrogen plasma treatment is performed on the substrate in the chamber. Accordingly, it is possible to obtain such effect of reducing the amount of Si particles produced in the reduction reaction of the fluorides. Thereby, it is possible to reduce the amount of Si particles to be mixed into the silicon-containing film during growth in the next film deposition step.

The generation method of hydrogen plasma is not limited in particular, and may be any method such as applying a voltage or a microwave to hydrogen gas after it is supplied into the chamber.

It is preferable that the hydrogen plasma treatment satisfies at least one of the following conditions 4 to 8:

condition 4: the treatment time is 1 to 10000 seconds,

condition 5: the flow rate of hydrogen gas is 10000 to 100000 sccm,

condition 6: the internal pressure of the chamber is 300 to 800 Pa,

condition 7: a pulsed discharge is performed at an applied electrical power of 0.03 to 0.1 W/cm² and a duty ratio of 5% to 50%, and

condition 8: the temperature of a heater for heating the substrate is 20 to 200 ° C.

If the treatment time is less than 1 second, the effect achieved from the generation of hydrogen plasma may not be sufficient. The same is true if the flow rate of hydrogen gas drops below 10000 sccm or the temperature of the heater falls below 20° C. On the other hand, if the treatment time exceeds 10000 seconds, it is difficult to further reduce the amount of Si particles in the chamber, thus leading to a prolonged takt time. The same is true if the flow rate of hydrogen gas exceeds 100000 sccm and the temperature of the heater exceeds 200° C. It is preferable that the condition 4 is appropriately set in accordance with the duty ratio.

If the internal pressure of the chamber is less than 300 Pa, hydrogen plasma is less likely to be generated. The same is true if the applied voltage is lower than 0.03 W/cm² and the duty ratio is less than 5%. On the other hand, if the internal pressure of the chamber exceeds 800 Pa, the discharge may become difficult to spread. Further, if the applied voltage exceeds 0.1 W/cm² or the duty ratio exceeds 50%, the etching effect of hydrogen plasma may become too strong to increase adversely the amount of Si particles.

<Usage of Method for Manufacturing Silicon-Containing Film>

The method for manufacturing a silicon-containing film is effective in mass production of silicon-containing films, and can be used in the method for manufacturing a photovoltaic device, a thin-film transistor or the like.

<Method for Manufacturing Photovoltaic Device>

The method for manufacturing a photovoltaic device includes the method for manufacturing a silicon-containing film according to the present invention. Specifically, a substrate disposed with a first electrode is loaded into the chamber, a photovoltaic unit is fabricated by laminating a p-type silicon layer, an i-type silicon layer and a n-type silicon layer in sequence on the surface of the substrate, and thereafter, the substrate fabricated with the photovoltaic unit is unloaded out of the chamber. The photovoltaic device is obtained after a second electrode is disposed on the substrate unloaded out of the chamber. Alternately, after the substrate is unloaded out of the chamber, the chamber is dry cleaned, and after that, the fluorides present in the chamber are reduced. Thereafter, the substrate disposed with the first electrode is loaded into the chamber and subjected to the abovementioned sequence of steps.

### EXAMPLES

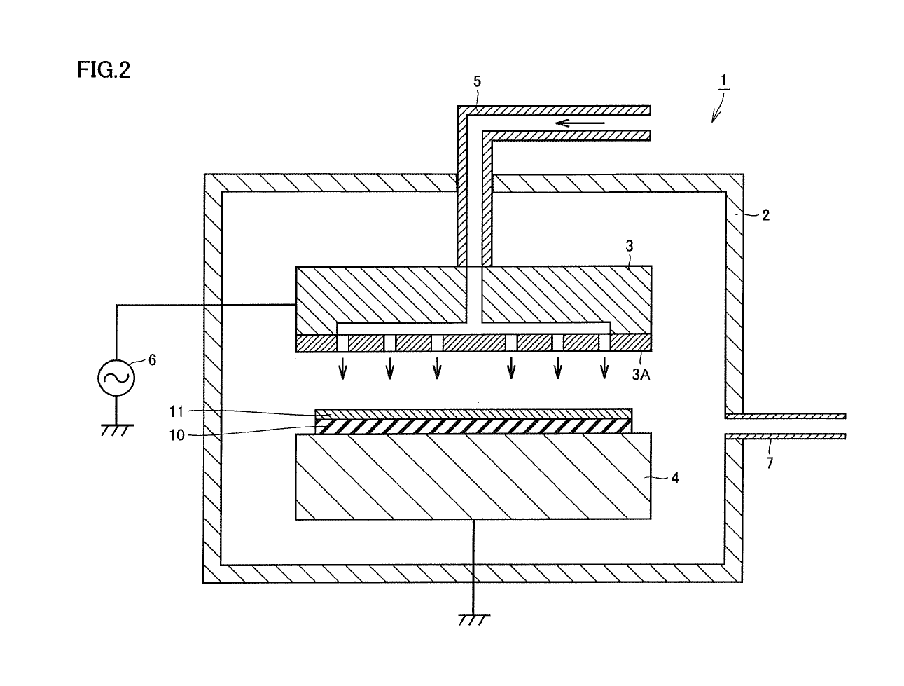

The structure of a plasma CVD device used in examples 1 to 3 is illustrated briefly. FIG. 2 is a cross sectional view schematically illustrating the structure of the plasma CVD device used in examples 1 to 3.

As illustrated in FIG. 2, a cathode electrode 3 and an anode electrode 4 are disposed facing each other in a chamber 2 of a plasma CVD device 1. Cathode electrode 3 is connected with a gas supply pipe 5. Cathode electrode 3 is provided with a shower plate 3A on a surface facing anode electrode 4. The gas supplied through gas supply pipe 5 passes through the interior of cathode electrode 3 and is ejected toward anode electrode 4 from an ejection face of shower plate 3A. A substrate 10 is placed on a surface of anode electrode 4 facing cathode electrode 3.

The gas supplied into chamber 2 via gas supply pipe 5 contains not only the source gas and the carrier gas to be used in the following step of <Depositing Silicon Film> but also a fluorine-containing gas to be used in the following step of <Dry Cleaning> and a reducing gas to be used in the following step of <Reducing Fluoride>.

Cathode electrode 3 is connected to a high frequency power supply 6 through the intermediary of a matching circuit (not shown). Meanwhile, anode electrode 4 is grounded. Thereby, it is possible to generate plasma in chamber 2.

Chamber 2 is provided with an exhaust pipe 7. Thereby, unnecessary gas in chamber 2 is exhausted to the outside of chamber 2 through exhaust pipe 7.

### Example 1

In Example 1, the residual amount of fluorides in chamber 2 was measured through varying the flow time of SiH₄ gas (reducing gas).

<Loading Substrate>

Substrate 10, which is made of glass and is disposed with transparent electrodes, was loaded into chamber 2 of CVD device 1 and was placed on the upper surface of anode electrode 4.

<Depositing Silicon Film>

SiH₄ gas (source gas) and H₂ (carrier gas) were supplied to chamber 2 through gas supply pipe 5, and plasma CVD method was used to deposit a silicon film 11 (having a film thickness of 300 μm) on the upper surface of substrate 10. The deposition conditions for silicon film 11 were listed as follows:

the flow rate of SiH₄ gas: 1 sccm,

the flow rate of H₂ gas: 10 sccm,

the temperature in chamber 2: 190° C.,

the internal pressure of chamber 2: 600 Pa,

the electrical power applied by high-frequency power source 6: 3400 W, and

the frequency of high-frequency power source 6: 11 MHz.

<Unloading Substrate>

substrate 10 deposited with silicon film 11 was unloaded out of the chamber 2.

<Dry Cleaning>

NF₃ gas and Ar gas were supplied to chamber 2 through gas supply pipe 5 to dry clean chamber 2. The supply of RF power and NF₃ gas was stopped at the time when Si film was cleaned away from the upper surface of anode electrode 4. The dry cleaning conditions were listed as follows:

the flow rate of NF₃ gas: 10 sccm,

the flow rate of Ar gas: 10 sccm,

the temperature in chamber 2: 160° C.,

the internal pressure of chamber 2: 150 Pa, and

the electrical power applied by high-frequency power source 6: 18000 W.

<Reducing Fluoride>

SiH₄ gas and H₂ gas were supplied to chamber 2 through gas supply pipe 5.

The supply conditions for SiH₄ gas were listed as follows:

the flow rate of SiH₄ gas: 2 sccm,

the supply time of SiH₄ gas (sec): 0, 50, 100, 150, 300, 450, 700

temperature in chamber 2: 190° C.,

the internal pressure of chamber 2: 1400 Pa, and

the electrical power applied by high-frequency power source 6: 0 W.

<Exhausting Gas>

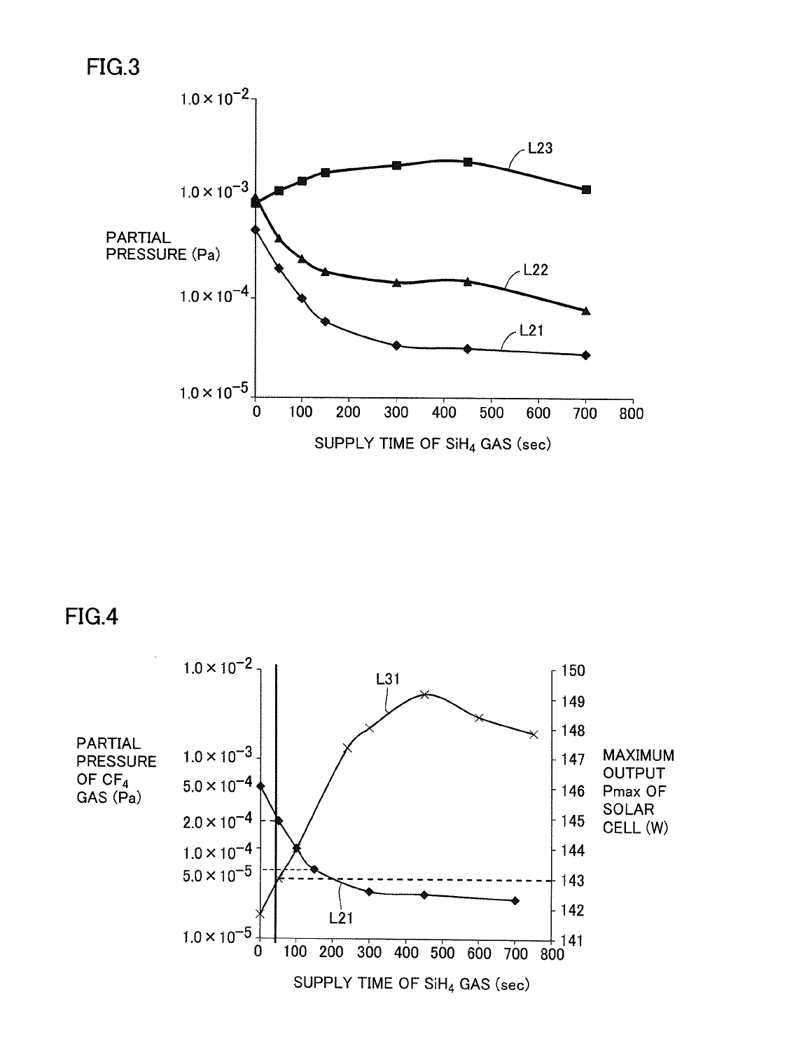

The gas in chamber 2 was exhausted to the outside of chamber 2 through exhaust pipe 7 until the ultimate vacuum of the chamber is 1 Pa or less. After that, the partial pressures of fluorides present in chamber 2 were measured by using a quadrupole mass spectrometer (mode number: VISION 1000 by MKS Instruments, Japan). The result is shown in FIG. 3.

FIG. 3 is a graph showing the measurement result of the partial pressures of fluorides relative to the supply time of SiH₄ gas, and curves L21, L22 and L23 in FIG. 3 represent the measurement results of the partial pressures of CF₄ gas, HF gas and SiF₄ gas, respectively.

As shown in FIG. 3, not only CF₄ but also HF gas and SiF₄ gas were present in chamber 2.

Moreover, the partial pressure of CF4 gas and the partial pressure of the HF gas decreased as the supply time of SiH₄ gas was lengthened. Meanwhile, the partial pressure of the SiF₄ gas did not change substantially even though the supply time of SiH₄ gas was lengthened. Thus, it was found that after SiH₄ gas is supplied, the partial pressures of the fluorides vary differently according to the types of the fluorides.

### Example 2

Example 2 was performed on focus of the partial pressure of CF₄ gas in chamber 2. Solar cells were manufactured by varying the supply time of SiH₄ gas, and the maximum output of each solar cell was measured.

<Loading Substrate>

A glass substrate (trade name: Asahi-U by Asahi Glass Co. Ltd.) having a SnO₂ film (functioning as a first electrode of the solar cell) deposited on the upper surface thereof through a thermal CVD method was prepared. The glass substrate was loaded into chamber 2 and was placed on the upper surface of anode electrode 4.

<Depositing Silicon Film>

SiH₄ gas, H₂ gas and B₂H₆ gas were supplied to chamber 2 through gas supply pipe 5. The flow rate of each of SiH₄ gas, H₂ gas and B₂H₆ gas were adjusted so as to dope 0.02% of boron atoms. Thereby, a p-type amorphous silicon layer (having a thickness of 20 nm) was deposited on the upper surface of the glass substrate.

Then, SiH₄ gas and H₂ gas were supplied to chamber 2 through gas supply pipe 5. Thereby, an i-type amorphous silicon layer (having a thickness of 280 nm) was deposited on the p-type amorphous silicon layer.

Next, Sinₜ gas, H₂ gas and PH₃ gas were supplied to chamber 2 through gas supply pipe 5. The flow rate of each of SiH₄ gas, H₂ gas and B₂H₆ gas were adjusted so as to dope 0.2% of phosphorus atoms. Thereby, a n-type amorphous silicon layer (having a thickness of 25 nm) was deposited on the i-type amorphous silicon layer.

Thereafter, according to the method described above, a p-type microcrystalline silicon layer, an i-type microcrystalline silicon layer and a n-type microcrystalline silicon layer (each having a thickness of 1.6 μm) were deposited sequentially on the n-type amorphous silicon layer.

<Unloading Substrate>

After the substrate deposited with the p-type amorphous silicon layer and the like was unloaded out of chamber 2, a zinc oxide film (having a thickness of 50 nm) and a silver film (having a thickness of 115 nm) were deposited sequentially on the n-type microcrystalline silicon layer by a magnetron sputtering method. Accordingly, a solar cell was fabricated.

<Dry Cleaning>

Chamber 2 was dry cleaned according to the method described above in Example 1.

<Reducing Fluoride>

CF₄ present in chamber 2 was reduced according to the method described above in Example 1 except that the supply time of SiH₄ gas was changed to 0, 50, 100, 250, 300, 450, 600 and 750 seconds.

<Exhausting Gas>

The gas in chamber 2 was exhausted to the outside of chamber 2 according to the method described above in Example 1.

Thereafter, the steps of <Loading Substrate>, <Depositing Silicon Film> and <Unloading Substrate> in the present example were performed sequentially. After that, the maximum output of the solar cell fabricated after the step of <Depositing Silicon Film> of the second time was measured.

The measurement results are shown in FIGS. 4 and 5. FIG. 4 is a graph showing the measurement results of the partial pressure of CF₄ gas and the maximum output

Pmax of the solar cell, respectively, relative to the supply time of SiH₄ gas. Curve L21 in FIG. 4 is identical to curve L21 in FIG. 3, and curve L31 in FIG. 4 shows the results of the present example. FIG. 5 is a graph showing the relationship between the partial pressure of CF₄ gas and the maximum output Pmax of the solar cell. It should be noted that the total pressure in the chamber at the time of measuring the partial pressure of CF₄ gas was 1 Pa, identical to that in Example 1 described in the above.

As shown in FIGS. 4 and 5, when the supply time of SiH₄ gas was 0 second, the partial pressure of CF₄ gas was 5×10⁻⁴ Pa, and the maximum output Pmax of the solar cell was less than 142 W. After SiH₄ gas had been introduced for 50 seconds, the partial pressure of CF₄ gas declined to 2×10⁻⁴ Pa, and the maximum output Pmax increased to 143 W. With longer supply of Sinₜ gas, the partial pressure of CF₄ gas declined rapidly to about 5×10⁻⁵ Pa, and the maximum output Pmax increased rapidly to 146 W. With further longer supply of SiH₄ gas, the partial pressure of CF₄ gas became lower than 5×10⁻⁵ Pa, and the maximum output Pmax became greater than 146 W. Therefore, it can be concluded that it is preferable to supply SiH₄ gas to reduce

CF₄ gas in such a way that the partial pressure of CF₄ gas at the end of the step of <Exhausting Gas> is 2×10⁻⁴ Pa or less and preferably the partial pressure of CF₄ gas at the end of the step of <Exhausting Gas> is 5×10⁻⁵ Pa or less.

Meanwhile, as shown in FIGS. 4 and 5, if SiH₄ gas was supplied longer than 450 seconds up to 600 seconds, the maximum output Pmax of the solar cell began to decline despite that the partial pressure of CF₄ gas had dropped to 3×10⁻⁵ Pa. When the supply time of SiH₄ gas was 700 seconds, the maximum output Pmax became lower than 148 W despite that the partial pressure of CF₄ gas had dropped to 2.5×10⁻⁵ Pa. The maximum output Pmax in the case where the supply time of SiH₄ gas was 700 seconds was sufficiently larger than the maximum output Pmax in the case where the supply time of SiH₄ gas was 0 second (i.e., the partial pressure of CF₄ gas was 5×10⁻¹ Pa). It was revealed that increasing the supply time of SiH₄ gas (i.e., decreasing the partial pressure of CF₄ gas) does not definitely improve the conversion efficiency, which means that the supply time of SiH₄ gas has an optimum range.

Although the reason therefore is not clear, it can be inferred as follows. In fabricating a photovoltaic device, since it is known that an active addition of some carbon atoms to the source gas may increase the maximum output Pmax, usually an amorphous SiC layer rather than an amorphous Si film is used to form the initial p-type silicon film. Although in the present example, the source gas containing carbon atoms is not supplied actively in depositing the p-type silicon film, it is anticipated that the p-type silicon film will be deposited by incorporating therein a part of carbon atoms contained in the gas remaining in the chamber. Thus, it is conceivable that if the partial pressure of CF₄ gas is reduced lower than necessary, the amount of carbon atoms to be incorporated in depositing the p-type silicon film will decrease rapidly, and consequently the maximum output Pmax degrades. If the supply time of SiH₄ gas is made longer, there arises such a problem that the throughput will decline. Thus, in order to achieve the balance between preventing the maximum output Pmax from degrading and preventing the throughput from declining, it is believed that the optimum range of the partial pressure of CF₄ gas is 2.5×10⁻⁵ to 2×10⁻⁴ Pa.

### Example 3

Example 3 was performed on focus of the partial pressure of CF₄ gas in chamber 2. The relationship between the supply time of SiH₄ gas and the partial pressure of CF₄ gas was investigated according to the same method as Example 1 described in the above except that the step of supplying SiH₄ gas was performed after substrate 10 was placed on the upper surface of anode electrode 4.

As described in the above Example 1, after the steps of <Loading Substrate>, <Depositing Silicon Film>, <Unloading Substrate> and <Dry Cleaning> had been performed, substrate 10 without being deposited with a silicon film was loaded into chamber 2 of plasma CVD device 1.

SiH₄ gas and H₂ gas were supplied through gas supply pipe 5. Then, after the step of <Exhausting Gas> as described in the above Example 1 was performed, the partial pressure of CF₄ gas at each supply time of SiH₄ gas was measured by using a quadrupole mass spectrometer.

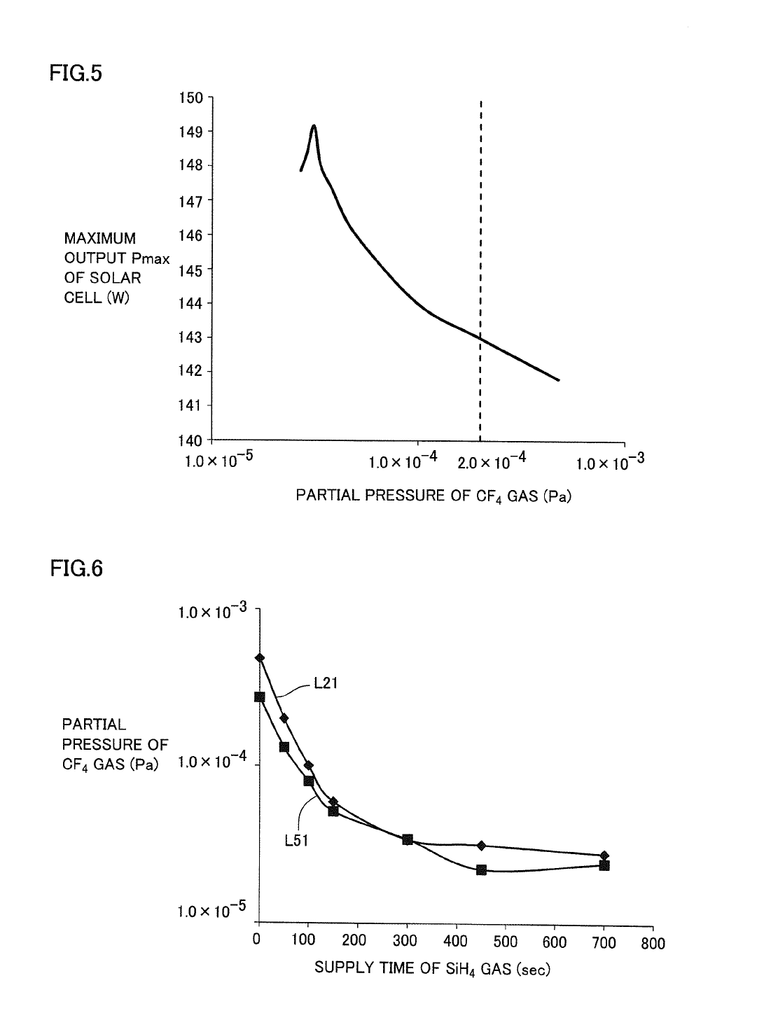

The result is shown in FIG. 6. FIG. 6 is a graph showing the measurement result of the partial pressure of CF₄ gas relative to the supply time of SiH₄ gas. Curve L21 is identical to curve L21 in FIG. 3, and curve L51 in FIG. 6 represents the result of the present example.

As shown in FIG. 6, when the supply time of SiH₄ gas was 0 second, the partial pressure of CF₄ gas in the case (curve L51) where SiH₄ gas is supplied after substrate 10 has been placed on the upper surface of anode electrode 4 was lower than that in the case (curve L21) without substrate 10 being placed on the upper surface of anode electrode 4. Accordingly, it is considered that CF₄ gas present in portions of anode electrode 4 where substrate 10 is placed is not detected by the quadrupole mass spectrometer. Thus, if SiH₄ gas is supplied after substrate 10 has been placed on the surface of anode electrode 4, CF₄ gas present in portions of anode electrode 4 where substrate 10 is placed is not exposed to SiH₄ gas, and thereby will not be reduced.

It should be understood that the embodiments and examples disclosed herein have been presented for the purpose of illustration and description but not limited in all aspects. It is intended that the scope of the present invention is not limited to the description above but defined by the scope of the claims and encompasses all modifications equivalent in meaning and scope to the claims.

### REFERENCE SIGNS UST

1: CVD device; 2: chamber; 3: cathode electrode; 4: anode electrode; 5: gas supply pipe; 6: high-frequency power source; 7: exhaust pipe; 10: substrate; 11: silicon film

1. A method for manufacturing a silicon-containing film, comprising:
a first step of loading a substrate into a chamber;
a second step of depositing a silicon-containing film on a surface of said substrate in said chamber;
a third step of unloading said substrate deposited with said silicon-containing film out of said chamber;
a fourth step of dry cleaning said chamber with a fluorine-containing gas;
a fifth step of supplying a reducing gas into said chamber to reduce fluoride present in said chamber; and
a sixth step of exhausting gas in said chamber until a pressure of said chamber is A (Pa),
in said fifth step, said reducing gas being supplied into said chamber in such a way that a partial pressure of CF₄ gas in said chamber is A×(2.0×10⁻⁴) Pa or less at the end of said sixth step.

2. The method for manufacturing a silicon-containing film according to claim 1, wherein said first step, said second step, said third step, said fourth step, said fifth step and said sixth step (S106-) are performed repeatedly.

3. The method for manufacturing a silicon-containing film according to claim 1, wherein said fifth step and said sixth step are additionally performed between said first step and said second step.

4. The method for manufacturing a silicon-containing film according to claim 1, wherein said reducing gas contains Si H₄ gas.

5. The method for manufacturing a silicon-containing film according to claim 1, wherein said fifth step is performed under at least one condition among
a condition that a supply time of said reducing gas is 10 to 1800 seconds,
a condition that a flow rate of said reducing gas is 1000 to 100000 sccm, and
a condition that an internal pressure of said chamber is 300 to 5000 Pa.

6. The method for manufacturing a silicon-containing film according to claim 1, further comprising a seventh step of performing a hydrogen plasma treatment in said chamber subsequent to said sixth step.

7. The method for manufacturing a silicon-containing film according to claim 6, wherein said seventh step is performed under at least one condition among
a condition that a treatment time of said hydrogen plasma treatment is 1 to 10000 seconds,
a condition that a flow rate of hydrogen gas is 10000 to 100000 sccm,
a condition that an internal pressure of said chamber is 300 to 800 Pa,
a condition that a pulsed discharge is performed at an applied electrical power of 0.03 to 0.1 W/cm² and a duty ratio of 5% to 50%, and
a condition that a temperature of a heater for heating said substrate is 20 to 200° C.

8. The method for manufacturing a silicon-containing film according to claim 1, wherein said silicon-containing film is deposited on the surface of said substrate according to a chemical vapor deposition method in said second step.

9. A method for manufacturing a photovoltaic device comprising the method for manufacturing a silicon-containing film according to claim 1.

10. The method for manufacturing a photovoltaic device according to claim 9, wherein said reducing gas is supplied into said chamber in said fifth step in such a way that a partial pressure of CF₄ gas in said chamber is A×(2.5×10⁻⁵) Pa or more at the end of said sixth step.
